(19) United States
(12) Patent Application Publication
(10) Pub. No.: US 2010/0081248 A1
(43) Pub. Date: Apr. 1, 2010

(54) METHOD FOR MANUFACTURING SEMICONDUCTOR DEVICE

(75) Inventor: Dong Geun LEE, Icheon-si (KR)

Correspondence Address: AMPACC Law Group, 3500 188th Street S.W., Suite 103, Lynnwood, WA, 98037, US

(73) Assignee: Hynix Semiconductor Inc., Icheon-si (KR)

(21) Appl. No.: 12/495,731

(22) Filed: Jun. 30, 2009

(30) Foreign Application Priority Data
Sep. 29, 2008 (KR) 10-2008-0095360

(51) Int. Cl. H01L 21/02

(52) U.S. Cl. 438/386; 257/E21.01

(57) ABSTRACT

A method for manufacturing a semiconductor device comprises forming a first plate electrode that defines a storage node region over a semiconductor substrate, forming a first dielectric film at sidewalls of the storage node region, forming a storage node over the storage node region, and forming a second dielectric film and a second plate electrode over the resulting structure, thereby preventing collapse of the storage node and also preventing generation of defects by electric short between capacitors.

### CROSS-REFERENCE TO RELATED APPLICATION

The priority of Korean patent application No. 10-2008-0095360 filed Sep. 29, 2008, the disclosure of which is hereby incorporated in its entirety by reference, is claimed.

### BACKGROUND OF THE INVENTION

The present invention generally relates to a method for manufacturing a semiconductor device, and more specifically, to a method for manufacturing a capacitor.

As the area occupied by a capacitor is decreased due to increasing integration of semiconductor devices, the effective surface of the capacitor is decreased so that it is impossible to secure sufficient capacitance of the capacitor.

The capacitance of a capacitor increases as a dielectric constant of a dielectric film and the effective surface of an electrode is increased. By using this characteristic, a method for securing the capacitance of the capacitor has been studied.

In order to secure the capacitance of the capacitor, the storage node is formed to have a three-dimensional concave or cylinder structure, thereby increasing the effective surface of the electrode.

A concave-structured capacitor is obtained as follows. A hole in which an electrode of the capacitor is to be formed is formed in an interlayer insulating film. A storage node of the capacitor is formed over the inner surface of the hole. A dielectric film and an upper electrode are deposited over the resulting structure. As a result, the concave-structured capacitor is formed.

However, due to the high integration of semiconductor devices, it is difficult to secure sufficient capacitance of the capacitor required per cell in the limited cell area with the concave-structured capacitor.

As a result, a cylinder-structured capacitor is suggested to provide a larger surface than the concave-structured capacitor.

FIGS. 1a to 1d are cross-sectional diagrams illustrating a method for manufacturing a conventional cylinder-structured capacitor.

As shown in FIG. 1a, a first interlayer insulating film 14, a nitride film 16 for supporting a capacitor, and a second interlayer insulating film 18 are formed over a semiconductor substrate 10 in which a storage node contact plug 12 is formed. A hole 20 in which a storage node is to be formed is formed so as to connect the storage node contact plug 12.

As shown in FIG. 1b, after a storage node 22 is formed in the hole 20, a chemical mechanical polishing (CMP) process is performed to expose the top portion of the second interlayer insulating film 18.

As shown in FIG. 1c, the first interlayer insulating film 14 and the second interlayer insulating film 18 are etched to form a capacitor dielectric film 24 over the storage node 22 and the nitride film 16.

As shown in FIG. 1d, a plate electrode 26 is formed over the dielectric film 24.

The cylinder-structured capacitor may use the inner and outer surfaces of the storage node as the effective surface of the capacitor. As a result, the cylinder-structured capacitor can have a larger capacitance than the concave-structured capacitor.

A dip-out process is required in order to remove the interlayer insulating film when the cylinder-structured capacitor is formed.

However, the dip-out process causes leaning and collapse of the storage node because the dip-out process is performed by a wet method using a chemical solution.

When the interlayer insulating film is removed while the aspect ratio of the storage node is increased due to the high integration of semiconductor devices, the supporting strength of the storage node is reduced to generate a bridge with other storage nodes, thereby degrading characteristics of the semiconductor device.

In order to prevent the bridge, the interlayer insulating film for manufacturing a capacitor is configured to include a nitride film. However, the nitride film causes defects in deposition of dielectric materials.

### BRIEF SUMMARY OF THE INVENTION

Various embodiments of the invention relates to a method for manufacturing a semiconductor device that prevents collapse of a storage node when removing an interlayer insulating film in order to increase capacitance of a capacitor.

According to an embodiment of the invention, a method for manufacturing a semiconductor device comprises: forming a first plate electrode that defines a storage node region (or hole) over a semiconductor substrate; forming a storage node in the storage node region; and forming a second dielectric film and a second plate electrode over the resulting structure.

Preferably, the forming-a-first-plate-electrode includes: forming a first plate material over the semiconductor substrate; and etching the first plate material with a storage node mask to form the storage node region.

Preferably, the forming-a-storage-node includes: forming a first dielectric film over the resulting structure including the first plate electrode; removing the first dielectric film disposed in the bottom of the storage node region; thereafter forming a storage node layer over the resulting structure including the first dielectric film; and thereafter etching the storage node layer and the first dielectric film to expose a top portion of the first plate electrode.

Preferably, the removing-the-first-dielectric-film includes forming a photoresist pattern that exposes the bottom portion of the storage node region to etch the first dielectric film with the photoresist pattern as an etching mask.

Preferably, the etching-the-storage-node-layer-and-the-first-dielectric-film includes: forming a photoresist pattern to expose the first dielectric film and the first storage node which are located at the top portion of the first plate electrode, and etching the storage node layer and the first dielectric film with the photoresist pattern as an etching mask.

Preferably, the etching-the-storage-node-layer-and-the-first-dielectric-film includes: forming an insulating film planarized over the resulting structure; and performing a planarizing process to expose the first plate electrode.

Preferably, the forming-a-storage-node includes: forming a first dielectric film over the resulting structure including the first plate electrode; performing a blanket-etching process on the first dielectric film; thereafter forming a storage node layer over the resulting structure; and thereafter etching the storage node layer to expose a top portion of the first plate electrode.

Preferably, the etching-the-storage-node-layer includes forming a photoresist pattern to expose the first storage node disposed over the first plate electrode, and etching the storage node layer with the photoresist pattern as an etching mask.

Preferably, the etching-the-storage-layer includes: forming an insulating film planarized over the resulting structure; and performing a planarizing process to expose the first plate electrode.

Preferably, after forming the second plate electrode, the method further comprises: forming an interlayer insulating film over the second plate electrode; etching the interlayer insulating film to form a metal line contact hole; and filling a conductive material in the metal line contact hole to form a metal line contact plug.

Preferably, the forming-a-metal-line-contact-hole includes etching the second plate electrode, the second dielectric film and the first plate electrode.

### BRIEF DESCRIPTION OF THE DRAWINGS

FIGS. 1a to 1d are cross-sectional diagrams illustrating a conventional method for manufacturing a semiconductor device; and

FIGS. 2a to 2i are cross-sectional diagrams illustrating a method for manufacturing a semiconductor device according to an embodiment of the invention.

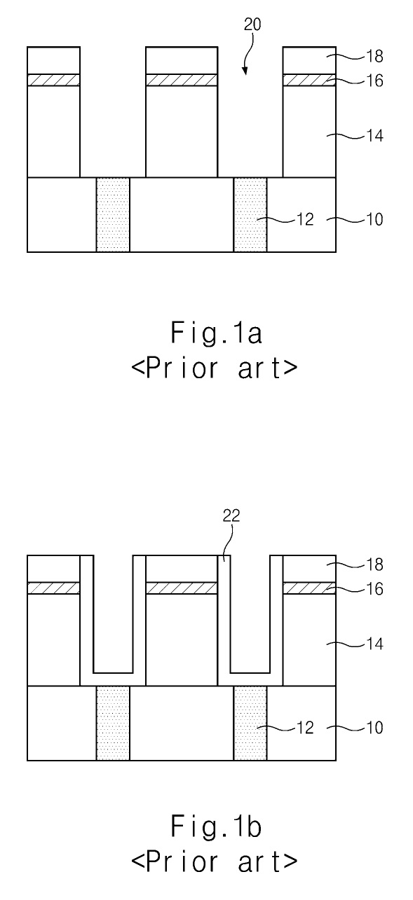

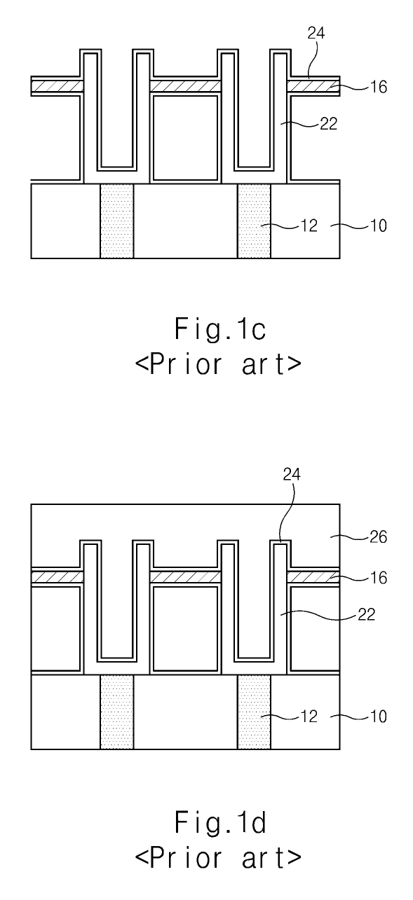

### DESCRIPTION OF EMBODIMENTS

Hereinafter, an embodiment of the invention will be illustrated in detail with reference to the attached drawings.

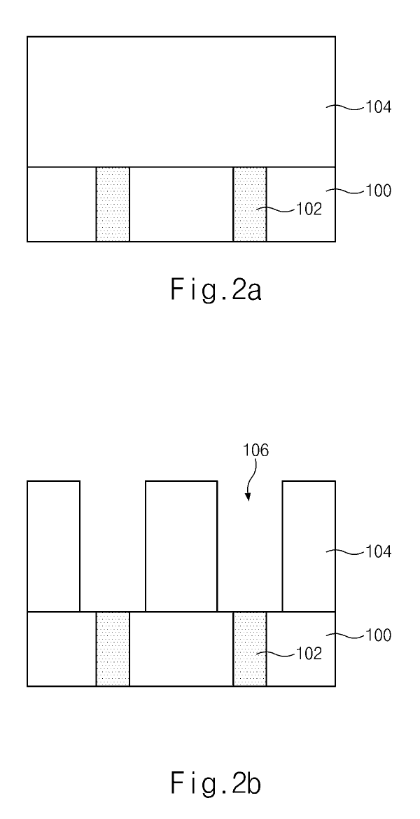

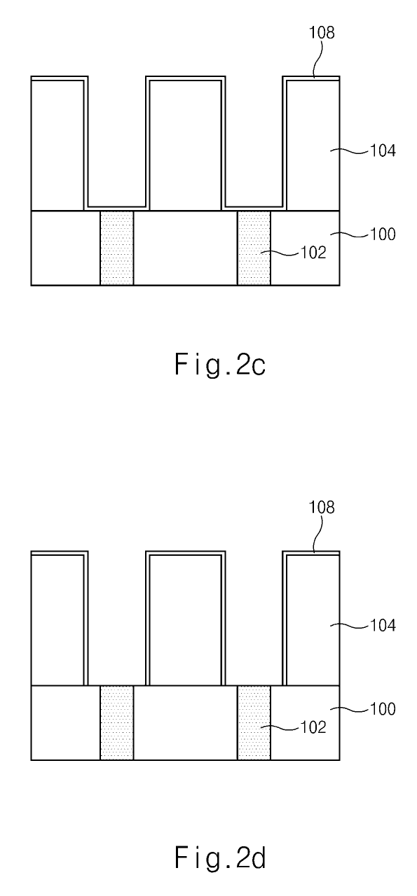

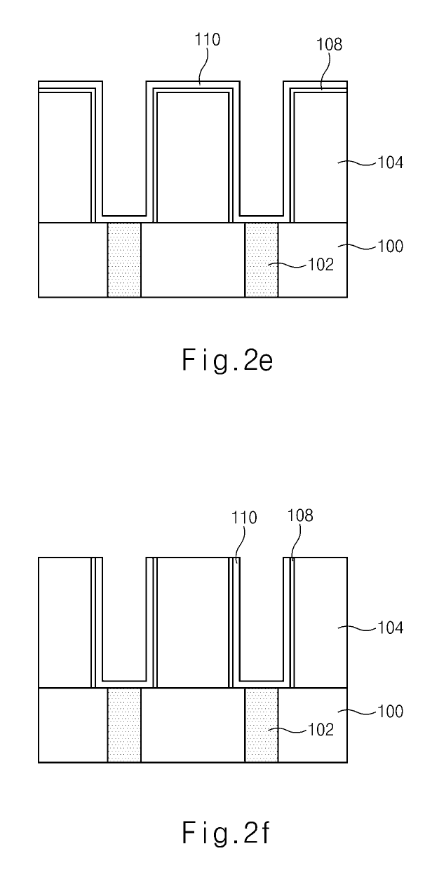

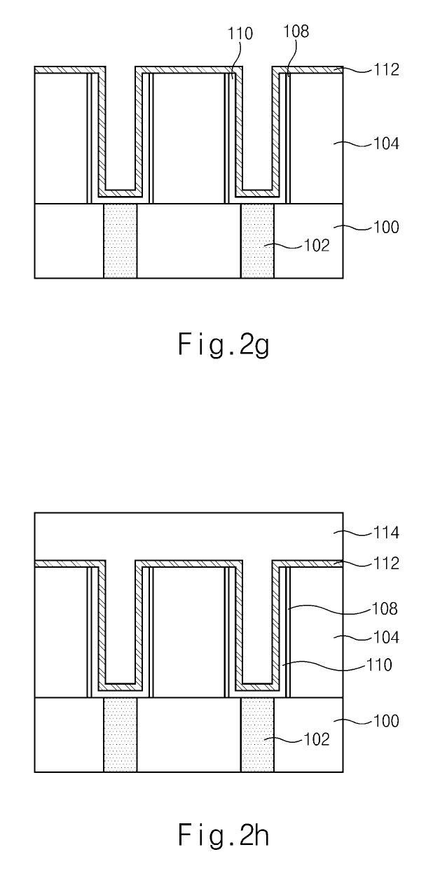

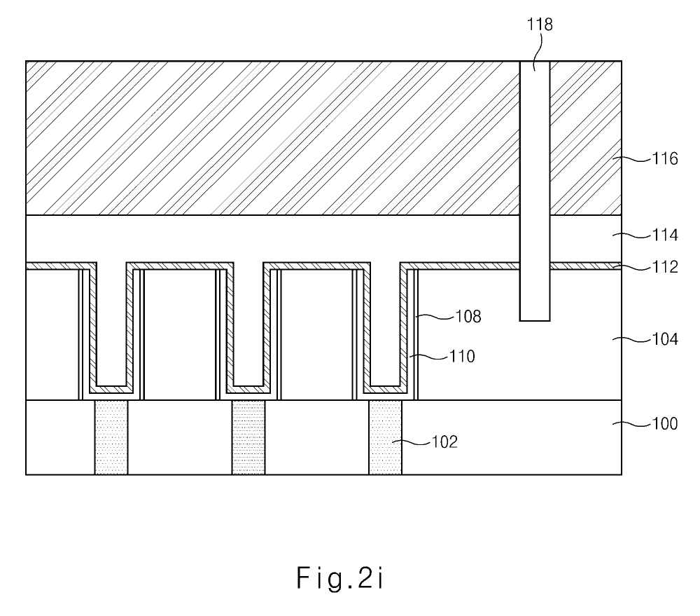

FIGS. 2a to 2i are cross-sectional diagrams illustrating a method for manufacturing a semiconductor device according to an embodiment of the invention.

Referring to FIG. 2a, a first plate electrode 104 is formed over a semiconductor substrate 100 including a storage node contact plug 102.

Since the first plate electrode 104 determines a height of a capacitor, a thickness of the first plate electrode 104 can be formed corresponding to the height of the capacitor. That is forming the plate electrode 104 instead of the interlayer insulating film in order to determine the height of the capacitor. As a result, the disclosed method may prevent collapse of the storage node when the interlayer insulating film is removed because a process for removing the interlayer insulating film is not performed.

As shown in FIG. 2b, a photoresist film (not shown) is coated over the first plate electrode 104. An exposing and developing process is performed with an exposure mask for defining a storage node to form a photoresist pattern (not shown).

The first plate electrode 104 is etched with the photoresist pattern as an etching mask to form a hole 106 in which a storage node is to be formed.

As shown in FIG. 2c, a first dielectric film 108 is formed in the hole 106 and over the first plate electrode 104.

As shown in FIG. 2d, a photoresist pattern (not shown) is formed over the first dielectric film 108. The first dielectric film 108 is etched with the photoresist pattern as an etching mask so that the first dielectric film 108 disposed at the bottom of the hole 106 is etched. A blanket-etching process is performed on the first dielectric film 108 to expose the storage node contact plug 102.

The blanket-etching process is performed to connect the storage node contact plug 102 to a storage node layer 110 which is to be formed in a subsequent process.

As shown in FIG. 2e, the storage node layer 110 is formed over the first dielectric film 108 and in the hole 106. The bottom of the storage node layer 110 contacts the storage node contact plug 102.

As shown in FIG. 2f, the storage node layer 110 and the first dielectric film 108 are etched to expose the top portion of the first plate electrode 104. As a result the storage node layer 110 is converted to a storage node that is defined within the hole 106. The process of removing part of the first dielectric film 108 does not correspond to the blanket-etching process of the first dielectric film 108, but to a mask process for etching the first dielectric film 108 to expose the contact plug 102 at the bottom of the hole 106. In order to etch the storage node layer 110 and the first dielectric film 108, an insulating film planarized (not shown) over the storage node layer 110 is formed, and a planarizing process is performed to expose the first plate electrode 104. Otherwise, a photoresist pattern (not shown) is formed to expose the first dielectric film 108 and the storage node 110 formed over the first plate electrode 104, and the storage node 110 and the first dielectric film 108 are removed using the photoresist pattern as an etching mask.

As shown in FIG. 2g, a second dielectric film 112 is formed over the storage node 110, the top portion of the first dielectric film 108 and the first plate electrode 104.

As shown in FIG. 2h, a second plate electrode 114 is formed over the second dielectric film 112.

As shown in FIG. 2i, an interlayer insulating film 116 is formed over the second plate electrode 114. A photoresist film is coated over the interlayer insulating film 116. An exposing and developing process is performed on the photoresist film to form a photoresist pattern (not shown) that defines a metal line contact plug region.

The interlayer insulating film 116 is etched with the photoresist pattern as an etching mask to form a metal line contact hole (not shown). A conductive material is filled in a metal line contact hole to form a metal line contact plug 118.

While the interlayer insulating film 116 is etched to form a metal line contact hole, the second plate electrode 114, the second dielectric film 112, and the first plate electrode 104 are etched to form a metal line contact hole (not shown). As a result, a metal line contact plug is formed to connect the second plate electrode 114 to the first plate electrode 104.

A metal line contact hole is formed over and into the first plate electrode 104 of the current invention. As a result, the metal line contact plug 118 is configured to connect the second plate electrode 114 electrically to the first plate electrode 104.

The method for electrically connecting the first plate electrode 104 to the second plate electrode 114 is not limited herein.

However, it is preferable to connect the first plate electrode 104 electrically to the second plate electrode 114 because the aforementioned method does not require any additional processes.

The disclosed method for manufacturing a capacitor does not comprise forming an interlayer insulating film but forming a plate electrode instead of the interlayer insulating film in order to determine the height of the capacitor. As a result, the disclosed method may prevent collapse of the storage node when the interlayer insulating film is removed because a process for removing the interlayer insulating film is not performed.

Also, the disclosed method may prevent degradation of characteristics of the semiconductor device due to the collapse of the storage node when the aspect ratio of the storage node becomes larger due to high integration.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device, the method comprising:
forming a first plate electrode that defines a storage node region over a semiconductor substrate;
forming a storage node, which includes a first dielectric film located between the sidewalls of the first plate electrode, in the storage node region; and
forming a second dielectric film and a second plate electrode over the resulting structure.

2. The method according to claim 1, wherein the forming-a-first-plate-electrode includes:
forming a first plate material over the semiconductor substrate; and
etching the first plate material with a storage node mask to form the storage node region.

3. The method according to claim 1, wherein the forming-a-storage-node includes:
forming a first dielectric film over the first plate electrode;
removing the first dielectric film disposed in the bottom of the storage node region;
thereafter, forming a storage node layer over the first dielectric film; and
thereafter, etching the storage node layer and the first dielectric film to expose a top portion of the first plate electrode.

4. The method according to claim 3, wherein the removing-the-first-dielectric-film includes forming a photoresist pattern that exposes the bottom portion of the storage node region to etch the first dielectric film with the photoresist pattern as an etching mask.

5. The method according to claim 3, wherein the etching-the-storage-node-layer-and-the-first-dielectric-film includes:
forming a photoresist pattern to expose the first dielectric film and the storage node layer which are located at the top portion of the first plate electrode, and
etching the storage node layer and the first dielectric film with the photoresist pattern as an etching mask.

6. The method according to claim 3, wherein the etching-the-storage-node-layer-and-the-first-dielectric-film includes:
forming an insulating film planarized over the resulting structure; and
performing a planarizing process to expose the first plate electrode.

7. The method according to claim 1, wherein the forming-a-storage-node includes:
forming a first dielectric film over the first plate electrode;
performing a blanket-etching process on the first dielectric film;
thereafter, forming a storage node layer; and
thereafter, etching the storage node layer to expose a top portion of the first plate electrode.

8. The method according to claim 7, wherein the etching-the-storage-node-layer includes forming a photoresist pattern to expose the storage node layer disposed over the first plate electrode, and etching the storage node layer with the photoresist pattern as an etching mask.

9. The method according to claim 7, wherein the etching-the-storage-layer includes:
forming an insulating film planarized over the resulting structure; and
performing a planarizing process to expose the first plate electrode.

10. The method according to claim 1, after forming the second plate electrode, the method further comprising:
forming an interlayer insulating film over the second plate electrode;
etching the interlayer insulating film to form a metal line contact hole; and
filling a conductive material in the metal line contact hole to form a metal line contact plug.

11. The method according to claim 10, wherein the forming-a-metal-line-contact-hole includes etching the second plate electrode, the second dielectric film and the first plate electrode.
